(19) United States
(12) Patent Application Publication
(10) Pub. No.: US 2015/0022059 A1
(43) Pub. Date: Jan. 22, 2015

(54) ELECTRONIC COMPONENT AND MANUFACTURING METHOD OF THE SAME

(71) Applicant: MURATA MANUFACTURING CO., LTD., Nagaokakyo-shi (JP)

(72) Inventors: Yoshifumi Saito, Nagaokakyo-shi (JP); Hiroaki Kaida, Nagaokakyo-shi (JP); Manabu Ibayashi, Nagaokakyo-shi (JP); Yuichiro Nagamine, Nagaokakyo-shi (JP); Katsuma Moroishi, Nagaokakyo-shi (JP); Takuya Kono, Nagaokakyo-shi (JP); Kazuhiro Mimura, Nagaokakyo-shi (JP)

(21) Appl. No.: 14/511,316

(22) Filed: Oct. 10, 2014

Related U.S. Application Data
(63) Continuation of application No. PCT/JP2013/063756, filed on May 17, 2013.

(30) Foreign Application Priority Data
May 18, 2012 (JP) 2012-114008

(51) Int. Cl. H01L 41/053; H03H 9/17; B23K 1/00

(52) U.S. Cl. CPC H01L 41/053; B23K 1/0016; H03H 9/17
USPC 310/344; 228/101

(57) ABSTRACT

A method of manufacturing an electronic component includes bonding a dome-shaped cap having a recess to a substrate on which are disposed a vibrator and a bonding material projecting in a rounded shape and surrounding the vibrator while the cap is disposed so that an open side of the recess faces the substrate and is relatively pressed to the substrate side. The bonding material is disposed so that, relative to the vibrator, an outer side end portion of the cap is located on the inner side of the bonding material or an inner side end portion of the cap is located on the outer side of the bonding material.

### CROSS REFERENCE TO RELATED APPLICATIONS

The present application is a continuation of International application No. PCT/JP2013/063756, filed May 17, 2013, which claims priority to Japanese Patent Application No. 2012-114008, filed May 18, 2012, the entire contents of each of which are incorporated herein by reference.

### FIELD OF THE INVENTION

The present invention relates to electronic components and manufacturing methods of the stated electronic components.

### BACKGROUND OF THE INVENTION

Quartz vibrators having quartz vibrating elements are known at present. In a quartz vibrator, a quartz vibrating element is generally disposed in a sealed space. This reduces influence of disturbance that is applied to the quartz vibrating element.

The sealed space is formed by bonding a substrate and a cap together via a bonding material, or the like (for example, see Patent Document 1).
Patent Document 1: Japanese Unexamined Patent Application Publication No. 2000-223604

### SUMMARY OF THE INVENTION

In a process of forming a sealed space, a bonding material is formed on a substrate through plating or the like, thereafter a cap is disposed on the bonding material, for example. Next, the cap and the substrate are bonded to each other by welding or the like via the bonding material. At this time, the cap and the substrate are bonded to each other while pressing the cap on the bonding material in a direction toward the substrate. The surface of the bonding material formed through plating or the like projects in a rounded shape. Accordingly, when the cap is pressed from the upper side of the bonding material in the direction toward the substrate, the cap moves along a slope of the surface of the bonding material so that the position of the cap is likely to be shifted. If the position of the cap is shifted, the sealed space is not appropriately formed so that vibration characteristics of the quartz vibrating element are deteriorated in some case. This problem is not specific only to quartz vibrators, but common to all electronic components that include vibrators.

A primary object of the present invention is to provide a manufacturing method of an electronic component in which vibration characteristics of a vibrator are unlikely to be deteriorated.

A manufacturing method of an electronic component according to the present invention includes a bonding step of bonding, using a bonding material, a dome-shaped cap having a recess to a substrate on which disposed are a vibrator and the bonding material projecting in a rounded shape and surrounding the vibrator while the cap is disposed so that an open side of the recess faces the substrate and is relatively pressed to the substrate side. In the bonding step, the bonding material is disposed so that an outer side end portion of a bonding target area of the cap to be bonded to the substrate is located on the inner side from the top of the bonding material or an inner side end portion of the bonding target area is located on the outer side from the top of the bonding material.

According to a specific aspect of the manufacturing method of the electronic component of the present invention, the bonding material is made of metal.

According to another specific aspect of the manufacturing method of the electronic component of the present invention, a quartz vibrating element is used as the vibrator.

An electronic component according to the present invention includes a substrate, a cap, a bonding material, and a vibrator. The cap is disposed on the substrate. The cap forms a sealed space along with the substrate. The cap has a dome shape. The bonding material bonds the substrate and the cap together. The vibrator is disposed on the substrate within the sealed space. An area of the cap to be bonded to the bonding material is located on the outer side or the inner side from the center of the bonding material in a width direction thereof.

According to the present invention, a manufacturing method of an electronic component in which vibration characteristics of a vibrator are unlikely to be deteriorated can be provided.

### BRIEF DESCRIPTION OF THE DRAWINGS

FIG. 1 is a schematic cross-sectional view illustrating a manufacturing method of an electronic component according to a first embodiment of the present invention.

FIG. 2 is another schematic cross-sectional view illustrating the manufacturing method of the electronic component according to the first embodiment of the present invention.

FIG. 3 is a schematic cross-sectional view illustrating a known manufacturing method of an electronic component.

FIG. 4 is a schematic cross-sectional view of an electronic component manufactured by the manufacturing method according to the first embodiment of the present invention.

FIG. 5 is a schematic cross-sectional view illustrating a manufacturing method of an electronic component according to a second embodiment of the present invention.

FIG. 6 is a schematic cross-sectional view of an electronic component manufactured by the manufacturing method according to the second embodiment of the present invention.

### DETAILED DESCRIPTION OF THE PREFERRED EMBODIMENTS

Examples of preferred embodiments for carrying out the present invention will be described hereinafter. Note, however, that the following embodiments are merely examples. The present invention is not intended to be limited to the following embodiments in any way.

Furthermore, in the drawings referred to in the embodiments and the like, members having functions that are substantially identical are given identical reference numerals. The drawings referred to in the embodiments and the like are schematic depictions, and as such the ratios of dimensions and so on of objects depicted in the drawings may differ from the actual ratios of dimensions and so on of those objects. The ratios of dimensions and so on of the objects may differ from drawing to drawing as well. The specific ratios of dimensions and so on of objects should be understood from the following descriptions.

### First Embodiment

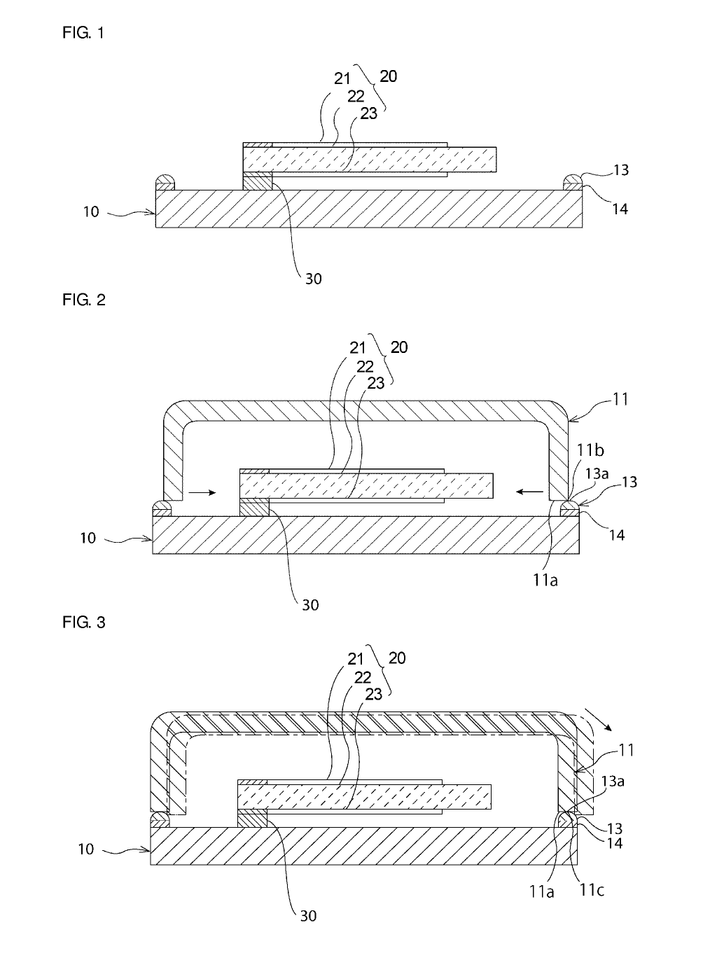

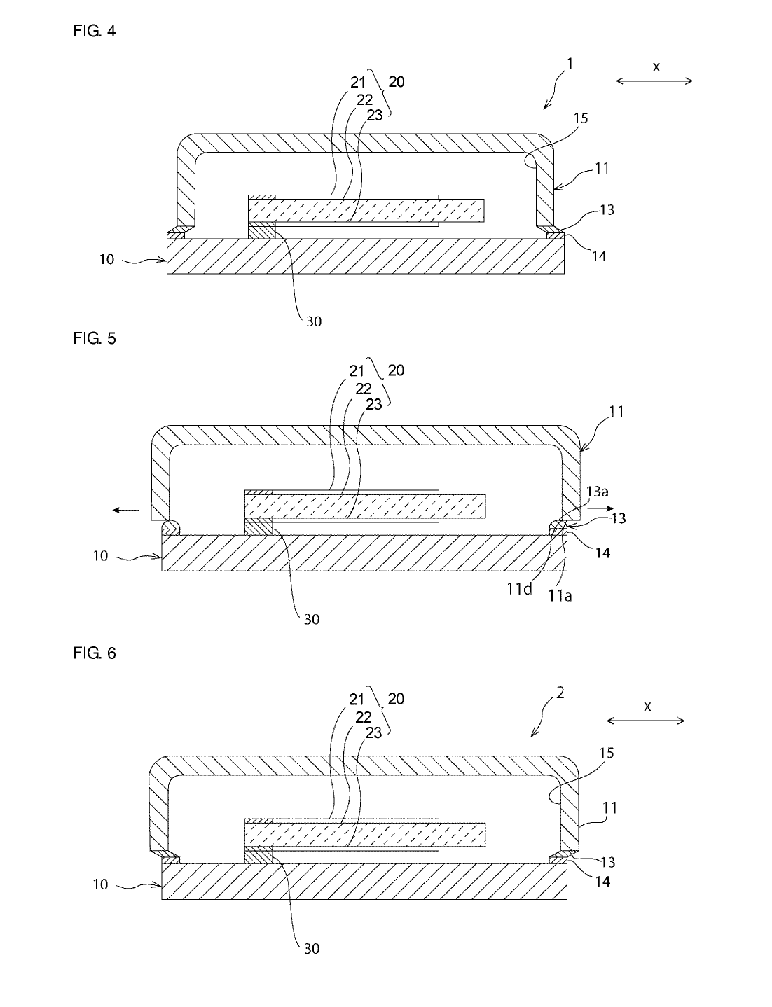

FIG. 1 and FIG. 2 are schematic cross-sectional views each illustrating a manufacturing method of an electronic component according to a first embodiment. FIG. 3 is a schematic cross-sectional view illustrating a known manufacturing method of an electronic component. FIG. 4 is a schematic cross-sectional view of an electronic component manufactured by the manufacturing method according to the first embodiment. The manufacturing method of an electronic component 1 according to the present embodiment will be described with reference to FIGS. 1 through 4.

First, as shown in FIG. 1, a substrate 10 is prepared. The substrate 10 is formed in a plate shape. The material of the substrate 10 is not limited to any specific one. The substrate 10 can be configured with, for example, metal such as iron, aluminum or the like, an alloy such as stainless steel or the like, or a ceramic material such as alumina or the like.

Next, a supporting member 30 is disposed on the substrate 10. The supporting member 30 can be configured with, for example, an insulation member such as ceramics or the like, or a conductive material such as a metal member or the like. Note that the electronic component does not necessarily need a supporting member in the present invention. The supporting member 30 can be disposed on the substrate 10 using a conductive adhesive, solder, or the like.

Subsequently, a vibrator 20 is mounted on the substrate 10. To be more specific, a conductive adhesive is applied on the supporting member 30, and then the vibrator 20 is disposed onto the conductive adhesive. Note that, in the present invention, the vibrator may be supported on the substrate via the conductive adhesive.

The vibrator 20 is configured with a piezoelectric vibrator. More specifically, the vibrator 20 is configured with a quartz vibrating element. However, in the present invention, the vibrator does not necessarily need to be a piezoelectric vibrator. The vibrator may be, for example, an elastic wave element such as a surface acoustic wave element or the like.

Specifically, in the present embodiment, the vibrator 20 includes a piezoelectric substrate 22 formed of quartz, and a pair of electrodes 21 and 23. The electrode 21 is formed on one main surface of the piezoelectric substrate 22, while the electrode 23 is formed on the other main surface of the piezoelectric substrate 22. A voltage is applied to the piezoelectric substrate 22 with the electrodes 21 and 23. The electrodes 21 and 23 can be formed with, for example, metal such as aluminum, silver, copper, gold or the like, an alloy containing one or more of the above types of metal, or the like.

Next, a conductive layer 14 is disposed on the substrate 10. The conductive layer 14 is disposed on the substrate 10 so as to surround the vibrator 20. The conductive layer 14 can be configured with metal or the like, for example.

Subsequently, a bonding material 13 is disposed on the substrate 10. More specifically, the bonding material 13 is disposed on the conductive layer 14. The bonding material 13 projects in a rounded shape in the case where the bonding material 13 is formed through plating. The bonding material 13 surrounds the vibrator 20. Material such as an Au/Sn-based alloy, an Ag/Cu-based alloy, or the like can be used for the bonding material 13; preferably used is an Au/Sn-based alloy. Note that in the present invention, the conductive layer is not necessarily needed to be disposed on the substrate, and the bonding material may be disposed directly on the substrate.

Next, as shown in FIG. 2, a cap 11 is disposed on the substrate 10. The cap 11 has a dome shape having a recess. The cap 11 and the substrate 10 are bonded to each other with the bonding material 13 while the cap 11 is disposed so that an open side of the recess thereof faces the substrate 10 and is relatively pressed to the substrate 10 side.

Incidentally, as shown in FIG. 3, in the known process of bonding the cap 11 and the substrate 10 together, the bonding material 13 is disposed on the substrate 10 so that a center portion 11c of a bonding target area 11a of the cap 11 to be bonded to the substrate 10 is located on a top 13a of the bonding material 13. Therefore, in the case where the cap 11 and the substrate 10 are bonded to each other with the bonding material 13 while relatively pressing the cap 11 to the substrate 10 side, the cap 11 moves along a slope of the surface of the bonding material 13 so that the position of the cap 11 is shifted in some case.

As opposed to this, as shown in FIG. 2, in the process of bonding the cap 11 and the substrate 10 together in the present embodiment, the bonding material 13 is disposed on the substrate 10 so that an outer side end portion 11b of the cap 11 is located on the inner side from the top 13a of the bonding material 13. Since the bonding material 13 is formed projecting in a rounded shape, a force directed toward the inner side of the substrate 10 is exerted on the entirety of the bonding target area 11a of the cap 11 in the case where the cap 11 is relatively pressed to the substrate 10 side so as to bond the cap 11 and the substrate 10 together with the bonding material 13. This makes it possible to suppress the position of the cap 11 from being shifted on the surface of the bonding material 13. Accordingly, it is possible to manufacture an electronic apparatus 1 in which vibration characteristics of the vibrator 20 are unlikely to be deteriorated.

The material of the cap 11 is not limited to any specific one. The cap 11 can be configured with the same material as that of the substrate 10. The substrate 10 and the cap 11 may be configured with different materials from each other, or may be configured with the same material.

Next, the substrate 10 and the cap 11 are bonded to each other via the bonding material 13 to form a sealed space 15 (see FIG. 4) so that the vibrator 20 is sealed within the sealed space 15. The bonding can be carried out through welding or the like. The bonding may be carried out in an atmosphere such as an air atmosphere, and an inert gas atmosphere such as a nitrogen gas atmosphere and an argon gas atmosphere. Note that in the present invention, the bonding material may extend to side portions of the cap 11.

Within the sealed space 15, an electronic component chip (not illustrated) may be disposed. A thermistor or the like can be cited as the electronic component chip.

Through the process described above, the electronic component 1 can be completed.

As shown in FIG. 4, the electronic component 1 manufactured by the manufacturing method according to the present embodiment includes the substrate 10, the cap 11, the bonding material 13, the conductive layer 14, and the vibrator 20. The cap 11 is disposed on the substrate 10 and forms the sealed space 15 along with the substrate 10. The bonding material 13 bonds the substrate 10 and the cap 11 together. The vibrator 20 is disposed on the substrate 10 within the sealed space 15. In the electronic component 1 according to the present embodiment, an area of the cap 11 that is bonded to the bonding material 13 is located on the inner side from the center of the bonding material 13 in a width direction (x direction) thereof.

Another example of preferred embodiment for carrying out the present invention will be described hereinafter. Note that in the following description, members having functions that are substantially identical with those of the members in the first embodiment are given identical reference numerals, and description thereof is omitted herein.

### Second Embodiment

FIG. 5 is a schematic cross-sectional view illustrating a manufacturing method of an electronic component according to a second embodiment. FIG. 6 is a schematic cross-sectional view of an electronic component manufactured by the manufacturing method according to the second embodiment. In the present embodiment, as shown in FIG. 5, in the process of bonding the cap 11 and the substrate 10 together, the bonding material 13 is disposed on the substrate 10 so that an inner side end portion 11d of the cap 11 is located on the outer side from the top 13a of the bonding material 13. Since the bonding material 13 is formed projecting in a rounded shape, a force directed toward the outer side of the substrate 10 is exerted on the bonding target area 11a of the cap 11 in the case where the cap 11 is relatively pressed to the substrate 10 side so as to bond the cap 11 to the substrate 10 with the bonding material 13. This makes it possible to suppress the position of the cap 11 from being shifted on the surface of the bonding material 13.

In an electronic component 2, an area of the cap 11 that is bonded to the bonding material 13 is located on the outer side from the center of the bonding material 13 in the width direction (x direction) thereof.

### REFERENCE SIGNS LIST

1, 2 electronic component
10 substrate
11 cap
11a bonding target area
11b outer side end portion
11c center portion
11d inner side end portion
13 bonding material
13a top
14 conductive layer
15 sealed space
20 vibrator
21, 23 electrode
22 piezoelectric substrate
30 supporting member

1. A method of manufacturing an electronic component, the method comprising:
bonding a dome-shaped cap having a recess to a substrate on which disposed are a vibrator and a bonding material, the bonding material projecting in a rounded shape and surrounding the vibrator, while the cap is disposed so that an open side of the recess faces the substrate and is relatively pressed to a side of the substrate,
wherein during the bonding, the bonding material is disposed so that, relative to the vibrator, an outer side end portion of the cap is located on an inner side of the bonding material or an inner side end portion of the cap is located on an outer side of the bonding material.

2. The method of manufacturing the electronic component according to claim 1,
wherein the bonding material is a metal.

3. The method of manufacturing the electronic component according to claim 2, wherein the metal is one of an Au/Sn-based alloy and an Ag/Cu-based alloy.

4. The method of manufacturing the electronic component according to claim 1,
wherein the vibrator is a quartz vibrating element.

5. The method of manufacturing the electronic component according to claim 1, further comprising:
disposing a conductive layer on the substrate so as to surround the vibrator, and
wherein the bonding material is disposed on the conductive layer.

6. An electronic component comprising:
a substrate;
a dome-shaped cap disposed on the substrate and forming a sealed space along with the substrate;
a bonding material bonding the substrate and the cap together; and
a vibrator disposed on the substrate within the sealed space,
wherein, relative to vibrator, an area of the cap bonded to the bonding material is located on an outer side or an inner side of the bonding material in a width direction of the bonding material.

7. The electronic component according to claim 6, wherein the bonding material is a metal.

8. The electronic component according to claim 7, wherein the metal is one of an Au/Sn-based alloy and an Ag/Cu-based alloy.

9. The electronic component according to claim 6, wherein the vibrator is a quartz vibrating element.

10. The electronic component according to claim 6, further comprising a conductive layer between the bonding material and the substrate.
